(19) United States
(12) Patent Application Publication
(10) Pub. No.: US 2026/0318992 A1
(43) Pub. Date: Oct. 15, 2026

(54) MECHANIZED IRRIGATION MACHINE THAT USES CURRENT TRANSMITTERS TO FIND AN OPEN SWITCH DEVICE

(71) Applicant: LINDSAY CORPORATION, Omaha, NE (US)

(72) Inventors: Randy Wood, Omaha, NE (US); Brian Klawinski, Omaha, NE (US)

(21) Appl. No.: 19/178,457

(22) Filed: Apr. 14, 2025

(51) Int. Cl. G01R 31/327; A01G 25/09; A01G 25/16

(52) U.S. Cl. CPC G01R 31/3277; A01G 25/092; A01G 25/16

(57) ABSTRACT

A sensor unit comprises a first terminal, a second terminal, a voltage sensing switch, and a current transmitter. The first terminal and the second terminal are each configured to electrically connect to a device. The voltage sensing switch is configured to sense an electric voltage between the first terminal and the second terminal and to switch to a high-impedance state if the voltage between the first terminal and the second terminal is greater than a disconnect voltage level threshold. The current transmitter is configured to output a current transmitter signal if the voltage between the first terminal and the second terminal is greater than or equal to a first turn on voltage level threshold and less than or equal to a second turn on voltage level threshold.

### FIELD OF THE INVENTION

Embodiments of the current invention relate to mechanized irrigation systems that include a plurality of switch devices and electric circuit components to detect an open switch device.

### BACKGROUND OF THE INVENTION

Mechanized irrigation systems comprise a plurality of spaced-apart, motorized, and self-propelled towers which support a fluid-carrying conduit and sprayer system that sprays the fluid on one or more crops. In a center-pivot irrigation system, the conduit is coupled to a fluid source at a center pivot point, and the towers travel in a roughly circular path around the center pivot. Between each adjacent pair of towers is a successive one of a plurality of sections of the conduit, wherein each adjacent pair of conduit sections is coupled with a successive one of a plurality of joints that is flexible. The irrigation system also includes a safety circuit which electrically connects monitoring components at the center pivot (or other location) to all of the towers in a closed loop in order to monitor the safety and other operational aspects of the irrigation system. The irrigation system further includes a plurality of switch devices that are electrically connected to the safety circuit. Each switch device is either closed or open in response to safety or other operational issues in the irrigation system. For example, the switch devices may respond to alignment of each tower with its neighboring towers, over watering situations, encounters with end of run barricades, and so forth. All of the switch devices are closed under normal operating conditions. But, at least one switch device may open in response to safety or other adverse operational issues. A central controller, which controls the operation of the irrigation system, senses the open switch device and shuts down the operation of the irrigation system. The central controller may also transmit an error message which alerts a technician to attend the irrigation system and repair, replace, or reposition one or more of the towers, discover the reason for overwatering, or the like. A problem may arise with irrigation systems that include dozens of switch devices and towers and may be thousands of feet long. It may be difficult to determine which switch device has opened.

The background discussion is intended to provide information related to the present invention which is not necessarily prior art.

### SUMMARY OF THE INVENTION

Embodiments of the current invention address one or more of the above-mentioned problems and provide irrigation systems that include a respective one of a plurality of sensor units electrically connected to each switch device. Each sensor unit is configured to switch to a high-impedance state if the switch device to which it is electrically connected opens. The sensor unit then outputs a signal with an identifying code to the central controller. One embodiment of the sensor unit broadly comprises a first terminal, a second terminal, a voltage sensing switch, and a current transmitter. The first terminal and the second terminal are each configured to electrically connect to a device. The voltage sensing switch is configured to sense an electric voltage between the first terminal and the second terminal and to switch to a high-impedance state if the voltage between the first terminal and the second terminal is greater than a disconnect voltage level threshold. The current transmitter is configured to output a current transmitter signal if the voltage between the first terminal and the second terminal is greater than or equal to a first turn on voltage level threshold and less than or equal to a second turn on voltage level threshold.

Another embodiment of the current invention provides an irrigation system comprising a plurality of switch devices, a plurality of sensor units, and a central controller. Each switch device includes a first contact and a second contact and is either closed or open. Each switch device is electrically connected to at least one other switch device. Each sensor unit includes a first terminal, a second terminal, a voltage sensing switch, and a current transmitter. The first terminal is electrically connected to the first contact of a respective one of the switch devices, and the second terminal is electrically connected to the second contact of the respective one of the switch devices. The voltage sensing switch is configured to sense an electric voltage between the first terminal and the second terminal and to be in a high-impedance state if the voltage between the first terminal and the second terminal is greater than a disconnect voltage level threshold. The current transmitter is configured to output a current transmitter signal if the voltage between the first terminal and the second terminal is greater than or equal to a first turn on voltage level threshold and less than or equal to a second turn on voltage level threshold. The central controller is configured to output a safety signal having a voltage greater than the disconnect voltage level threshold such that the voltage sensing switch of one of the sensor units is in the high-impedance state if the switch device to which it is electrically connected opens.

Yet another embodiment of the current invention provides an irrigation system comprising a plurality of switch devices, a plurality of sensor units, and a central controller. Each switch device includes a first contact and a second contact and is either closed or open. Each switch device is electrically connected to at least one other switch device. Each sensor unit includes a first terminal, a second terminal, a voltage sensing switch, and a current transmitter. The first terminal is electrically connected to the first contact of a respective one of the switch devices, and the second terminal is electrically connected to the second contact of the respective one of the switch devices. The voltage sensing switch is configured to sense an electric voltage between the first terminal and the second terminal and to be in a high-impedance state if the voltage between the first terminal and the second terminal is greater than a disconnect voltage level threshold. The current transmitter is configured to output a current transmitter signal if the voltage between the first terminal and the second terminal is greater than or equal to a first turn on voltage level threshold and less than or equal to a second turn on voltage level threshold. The central controller is configured to output a sensor identification signal having a voltage greater than or equal to the first turn on voltage level threshold and less than or equal to the second turn on voltage level threshold such that the current transmitter of one of the sensor units outputs the current transmitter signal if the switch device to which it is electrically connected opens.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF DRAWINGS

Embodiments of the current invention are described in detail below with reference to the attached drawing figures, wherein:

FIG. 1 is a perspective environmental view of an irrigation system, constructed in accordance with various embodiments of the current invention, including a plurality of towers and a plurality of switch devices, each switch device associated with at least a portion of the towers, the irrigation system configured to determine a location or an identifier of an open switch device;

FIG. 2 is a schematic block diagram of a first configuration of a central controller, the switch devices, and a plurality of sensor units;

FIG. 3 is a schematic block diagram of the sensor unit;

FIG. 4 is a schematic block diagram of the electrical connection between the sensor unit and a first embodiment of the switch device; and

FIG. 5 is a schematic block diagram of a second configuration of the central controller, the switch devices, and the sensor units.

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE INVENTION

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

In the following description, the word “voltage” may be used to describe electric voltage, the word “current” may be used to describe electric current, and the word “power” may be used to describe electric power. In addition, the word “signal” may be used to describe an electromagnetic wave conducted through an electrically conductive medium in which a voltage and/or a current varies, or may be constant, over time.

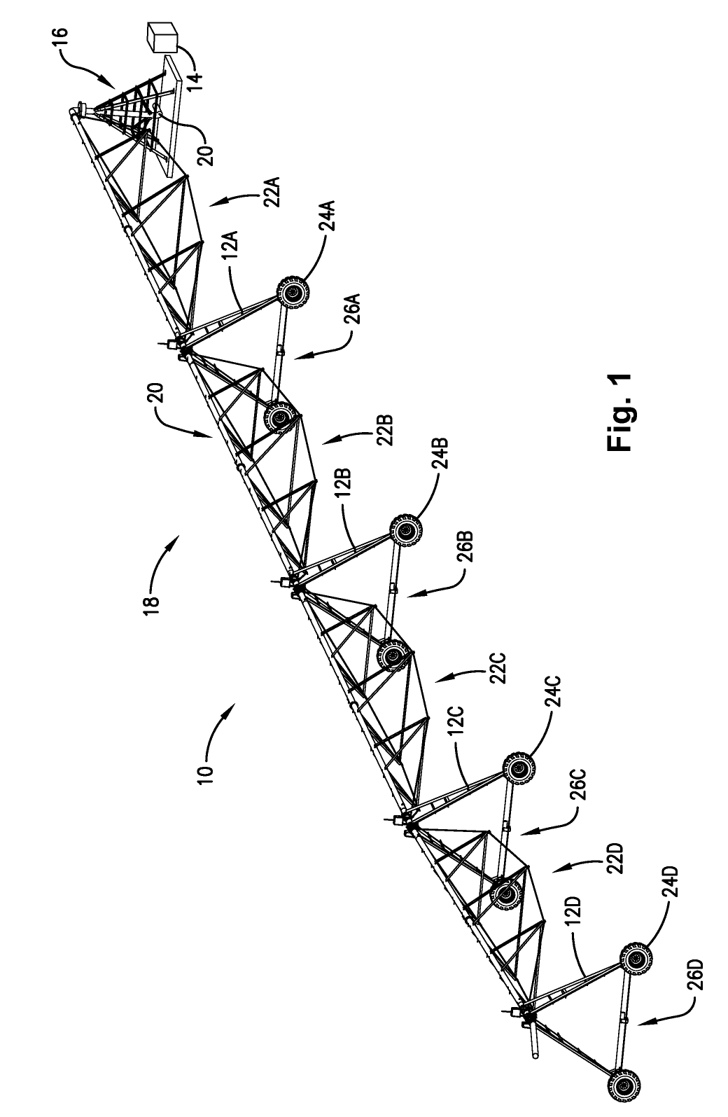

A mechanized irrigation system 10, constructed in accordance with various embodiments of the current invention, is shown in FIG. 1. The irrigation system 10 broadly comprises a plurality of towers 12 which support fluid delivery components along with a central controller 14 that controls operation of the irrigation system 10. An exemplary embodiment of the irrigation system 10, shown in FIG. 1, is a center pivot irrigation system and broadly comprises a fixed center pivot 16 and a main section 18 pivotally connected to the center pivot. The irrigation system 10 may also comprise an extension arm (also commonly referred to as a “swing arm” or “corner arm”) pivotally connected to the free end of the main section 18. The irrigation system 10 may also be embodied by a lateral, or linear, move apparatus which irrigates while moving in a linear, or near-linear, direction without departing from the scope of the current invention.

The fixed center pivot 16 may be a tower or any other support structure about which the main section 18 may pivot. The center pivot has access to a well, water tank, or other source of water or other fluid and may also be coupled with a tank or other source of agricultural products to inject fertilizers, pesticides and/or other chemicals into the water for application during irrigation. The center pivot 16 may supply water to a conduit 20 which carries the water along the length of the main section 18.

The main section 18 may comprise any number of mobile support towers 12A-D, the outermost tower 12D of which is referred to herein as an end tower. The towers 12A-D are connected to the fixed center pivot 16 and to one another by truss sections 22A-D or other supports to form a number of interconnected spans.

The towers 12 have wheels 24A-D, at least one of which is driven by suitable drive motors 26A-D. Each motor 26A-D turns at least one of its wheels 24A-D through a drive shaft to propel its tower 12 and thus the main section 18 in a circle about the center pivot 16 to irrigate a field. The motors 26 may also have several speeds or be equipped with variable speed drives. The operation of the motors 26A-D, such as whether they are on or off, the speed of travel, and the direction of travel, may be controlled with one or more electronic signals or digital data.

Each of the truss sections 22A-D carries or otherwise supports the conduit 20 and other fluid distribution mechanisms that are connected in fluid communication to the conduit 20. Fluid distribution mechanisms may include sprayers or diffusers, each optionally attached to a drop hose, or the like. Between each adjacent pair of towers 12A-D is a successive one of a plurality of sections of the conduit 20, wherein each adjacent pair of conduit 20 sections is coupled with a successive one of a plurality of joints that is flexible. In addition, the conduit 20 may include one or more valves which control the flow of water through the conduit 20. The opening and closing of the valves may be automatically controlled with an electronic signal or digital data.

The irrigation system 10 may also include wired or wireless communication electronic components that communicate with a communication network and allow the valves and the motors 26 to receive the electronic signals and/or digital data which control the operation of the valves and the motors 26.

The irrigation system 10 may also include an optional extension arm, or corner arm, (not shown) pivotally connected to the end tower 12D and may be supported by a swing tower 12 with steerable wheels 24 driven by a motor 26. The extension arm may be joined to the end tower 12D by an articulating pivot joint. The extension arm is folded in relative to the end tower 12D when it is not irrigating a corner of a field and may be pivoted outwardly away from the end tower 12D while irrigating the corners of a field.

The irrigation system 10 illustrated in FIG. 1 has four towers 12A-D; however, it may comprise any number of towers, truss sections, wheels, and drive motors without departing from the scope of the current invention.

The irrigation system 10 may further include one or more sensors which measure the amount of water delivered from the irrigation system 10 to the crop. The sensors may communicate with the communication network to report the amount of delivered water. The water may be reported as a depth in units of millimeters (mm) or inches (in).

The irrigation system 10 further includes a safety circuit 30 for monitoring the safety and operational aspects of the irrigation system 10. The safety circuit 30 includes a plurality of switch devices 32, a plurality of sensor units 34, and a safety circuit monitor 36. Each switch device 32 is either closed or open in response to safety or operational issues in the irrigation system 10. The components of the safety circuit 30 operate in combination to identify which switch device 32 is open.

In its simplest form, the switch device 32 includes two terminals and a moveable contact therebetween in a single-pole, single-throw (SPST) configuration, wherein an electrical connection is made between the two terminals when the switch device 32 is closed, and there is no electrical connection between the two terminals when the switch device 32 is open. In other embodiments such as the one shown in FIG. 4, the switch device 32 has a common terminal (C), a normally open terminal (NO), and a normally closed terminal (NC) with a contact that moves between the normally open terminal NO and the normally closed terminal NC. When the switch device 32 is closed, there is an electrical connection between the common terminal C and the normally closed terminal NC. When the switch device 32 is open, there is an electrical connection between the common terminal C and the normally open terminal NO.

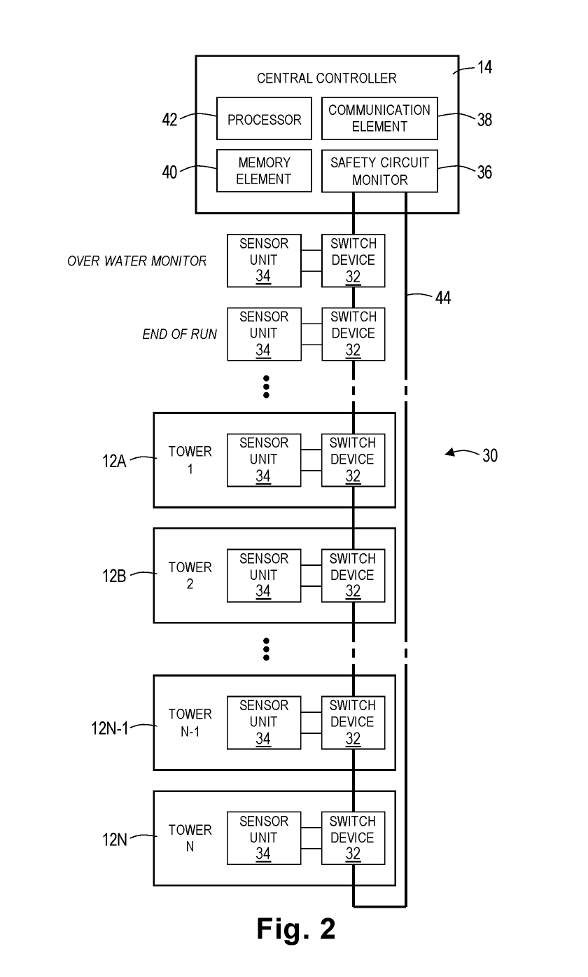

Referring to FIG. 2, the switch devices 32 may perform one or more functions, may be in communication with one or more sensors, mechanisms, or mechanical assemblies, and may be utilized in one or more locations of the irrigation system 10. For example, each tower 12 may include at least one switch device 32, as a safety switch, to respond to alignment of the tower 12 with its neighboring towers 12, wherein the switch device 32 is closed when the tower 12 is in proper alignment and the switch device 32 opens when the tower 12 is out of alignment. Another switch device 32 may respond to over watering situations, wherein the switch device 32 is closed when the irrigation system 10 is applying the proper amount of water to a given area, and the switch device 32 opens when one or more of the towers 12 stalls and applies too much water to the area. Yet another switch device 32 may be utilized in irrigation systems 10 which irrigate a partial circular area of land. Typically, these irrigation systems 10 include an end of run barricade that prevents the towers 12 from moving farther along the programmed path than allowed. Thus, these irrigation systems 10 may also include one or more switch devices 32 that respond to encounters with the end of run barricades, wherein the switch device 32 is closed when the towers 12 travel along the programmed path, and the switch device 32 opens when one or more towers 12 encounter one or more end of run barricades. In embodiments of the irrigation system 10 that include an extension arm, the extension arm may be considered the last tower 12N. The extension arm tower 12N may include one or more switch devices 32 which respond to operational aspects of the tower 12N. If any of the operational aspects of the extension arm tower 12N are not performing correctly, at least one of the switch devices 32 opens.

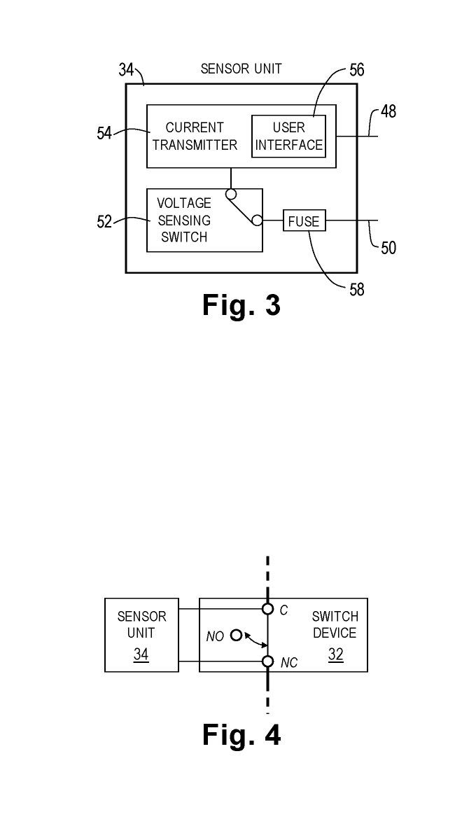

Each sensor unit 34 has a first terminal 48 and a second terminal 50 and includes, at least, a voltage sensing switch 52, a current transmitter 54, a user interface 56, and a fuse 58, as shown in FIG. 3. The voltage sensing switch 52 includes sensing circuitry voltage across the first and second terminals 48, 50 and/or current through the first and second terminals 48, 50. The voltage sensing switch 52 is also configured to be in, or switch to, a high-impedance/current-limiting mode according to the sensed voltage across the first and second terminals 48, 50. That is, the voltage sensing switch 52 operates in a low impedance state while the sensed voltage is less than or equal to a disconnect voltage level threshold. Low impedance is generally an impedance value which allows the current transmitter 54 to operate, i.e., output a selected value of current. In some embodiments, low impedance is less than one hundred (100) ohms. In other embodiments, low impedance is less than ten (10) ohms. When the sensed voltage is greater than the disconnect voltage level threshold, the voltage sensing switch 52 is in, or switches to, a high-impedance state and becomes a high-impedance component which limits the current flow through the sensor unit 34. High impedance is generally an impedance value which causes a large enough voltage drop in the safety circuit 30, or reduces the current in the safety circuit 30 sufficiently, as a result of the switch device 32 (to which the sensor unit 34 is electrically connected) opening, for the safety circuit monitor 36 to detect the open switch device 32. In some embodiments, high impedance is greater than one thousand (1,000) ohms. In other embodiments, high impedance is on the order of megaohms or tens of megaohms. The high-impedance state of the voltage sensing switch 52 effectively turns the sensor unit 34 into an open circuit across the first and second terminals 48, 50.

The current transmitter 54 is electrically connected to the voltage sensing switch 52 and the first terminal 48 and includes active electronic circuitry, such as a current source, configured to output a current transmitter signal through the first terminal 48 and/or the second terminal 50. The current transmitter signal has a value. For example, the current transmitter signal may include a selective electric direct current level, such as being selected from approximately 4 milliamps (mA) to approximately 20 mA, or may include selective digital data, such as a selected sequence of pulses to present binary data, e.g., 0101, or selective pulse width modulated (PWM) signaling wherein a width of each pulse indicates the value. The current transmitter 54 is a low-impedance component. The current transmitter 54 outputs the current transmitter signal when the voltage across first and second terminals 48, 50 is within a certain range, that is greater than or equal to a first turn on voltage level threshold and less than or equal to a second turn on voltage level threshold, wherein the first and second turn on voltage level thresholds are each less than the disconnect voltage level threshold.

The user interface 56 includes switches, knobs, buttons, or the like which allow a technician or installer to input data that sets the value of the current transmitter signal at the time of installation or nearly any time during operation. The fuse 58 is sensitive to electric current flow and provides an open circuit when the current flowing through it exceeds a first current level threshold. When the fuse 58 is open, electric current does not flow through the sensor unit 34. The fuse is electrically connected to one of the first or second terminals 48, 50.

The sensor unit 34 may operate as follows. The voltage sensing switch 52 senses the voltage across first and second terminals 48, 50. While the voltage is less than the first and second turn on voltage level thresholds and the disconnect voltage level threshold, the sensor unit 34 is generally non-operational and presents a low impedance across the first and second terminals 48, 50. When the voltage across first and second terminals 48, 50 is between the first and second turn on voltage level thresholds, the current transmitter 54 turns on and outputs the current transmitter signal. When the voltage across first and second terminals 48, 50 is greater than the disconnect voltage level threshold, the voltage sensing switch 52 is in, or switches to, the high-impedance state which turns off the current transmitter 54 (if it was on) and limits the current flow through the sensor unit 34.

The value of the current transmitter signal is set through the user interface 56 and may vary according to an identification of the switch device 32 to which the sensor unit 34 is connected or another identifier of feature of the irrigation system 10. For example, if the switch device 32 is implemented in one of the towers 12, then the identification of the switch device 32 may vary according to the position or location of the tower 12. Accordingly, the value of the current transmitter signal may vary according to the position or location of the tower 12 or a distance from the center pivot 16. If the switch device 32 is implemented outside of one of the towers 12, then the switch device 32 may be assigned a number or other indicator, perhaps according to its function, that does not overlap with the identifications of the switch devices 32 implemented in the towers 12. Accordingly, the value of the current transmitter signal may vary according to the other assigned switch device identifiers.

The fuse 58 of the sensor unit 34 prevents the sensor unit 34 from failing or acting like a short circuit in the event of a current surge that inhibits normal operation of the sensor unit 34. In the absence of the fuse 58, a current surge, from a lightning strike or other unusual event, may damage the voltage sensing switch 52, causing it to stay in the low-impedance state – even if the voltage across the first and second terminals 48, 50 rises above the disconnect voltage level threshold. In the presence of the fuse 58, a current surge will blow the fuse, thereby creating an open circuit across the first and second terminals 48, 50.

Each sensor unit 34 is electrically connected to a respective one of the switch devices 32. If the switch device 32 has the SPST switch configuration, then the first terminal of the switch device 32 is electrically connected to the first terminal 48 of the sensor unit 34, and the second terminal of the switch device 32 is electrically connected to the second terminal 50 of the sensor unit 34. If the switch device 32 has the configuration shown in FIG. 4, then the first terminal 48 of the sensor unit 34 is electrically connected to the common terminal C of the switch device 32, and the second terminal 50 is electrically connected to the normally closed terminal NC, although the first terminal 48 may be electrically connected to the normally closed contact NC and the second terminal 50 may be electrically connected to the common terminal C.

The safety circuit monitor 36 outputs and receives an electronic safety signal and senses when the safety signal is not received. The safety circuit monitor 36 also receives the current transmitter signal when it is output from one of the sensor units 34. The safety circuit monitor 36 may include various combinations of a voltage source, a current source, a voltage sensor, a current sensor, an electric impedance sensor, an analog to digital converter (ADC), a wireless RF receiver, and the like. The safety circuit monitor 36 further includes a first port and a second port. The safety circuit monitor 36 may generate the safety signal as a voltage across the first and second ports, a current from one of the ports, and/or may detect the safety signal as an electric impedance across the first and second ports. An exemplary safety signal may be 120 V AC. Typically, the amount of current output by the safety signal source is limited to prevent current overload. The safety signal flows through all of the switch devices 32 when each switch device 32 is closed. While the safety signal is being output and received (as a result of all of the switch devices 32 being closed), the current is at a low, non-zero value, and/or the electric impedance is low. The safety circuit monitor 36 outputs a status signal to the processor 42 which has a first one of a plurality of values which indicates that all of the switch devices 32 are closed. When any of the switch devices 32 opens, the safety signal no longer flows in the safety circuit 30. The safety circuit monitor 36 detects the loss of the safety signal, stops outputting the safety signal, and outputs the status signal to the processor 42 having a second one of the values which indicates that one of the switch devices 32 is open. (The processor 42 may shut down the irrigation system 10 as described elsewhere.)

The safety circuit monitor 36 also outputs a sensor identification signal to the safety circuit 30 after the irrigation system 10 has been shut down following a misalignment, over watering, end of run barricade encounter, or other mishap. The sensor identification signal has a low voltage level (much less than the safety signal) which is meant to turn on, or power up, the current transmitter 54 of the sensor unit 34 connected to the switch device 32 which opened during the event that shut down the irrigation system 10.

When the sensor unit 34 that is electrically connected to the open switch device 32 receives the sensor identification signal, its current transmitter 54 outputs the current transmitter signal which has a value that varies according to the identification of the open switch device 32. The safety circuit monitor 36 receives the current transmitter signal and converts the analog current level or digital data value to the identification (e.g., a number) of the open switch device 32. Or, the safety circuit monitor 36 may determine the number or position of the tower 12 with the open switch device 32. The safety circuit monitor 36 may communicate or output a status signal which indicates either all switch devices 32 are closed or the identification or function of the open switch device 32 or a number or position of the tower 12 with the open switch device 32.

The safety circuit 30 further includes a first electrically conductive cable (wire) 44 having a plurality of segments or sections which electrically connects all of the components of the safety circuit 30. Referring to FIG. 2, a first segment of the first cable 44 electrically connects the safety circuit monitor 36 to a first switch device 32 utilized with over water monitoring. A second segment of the first cable 44 electrically connects the first switch device 32 to a second switch device 32 utilized with end of run barricade detection. Additional segments of the first cable 44 electrically connect any other switch devices 32 that are not utilized with one of the towers 12. Additional segments also electrically connect each switch device 32 utilized with a respective one of the towers 12. One or more segments of the first cable 44 also electrically connect the last tower 12N back to the safety circuit monitor 36. All of the switch devices 32 are electrically connected in series, with the second terminal of one switch device 32 connected to the first terminal of the next switch device 32. The safety circuit 30 forms an electrically conductive closed circuit path when all of the switch devices 32 are closed, which may be known as a “normal state”.

The communication element 38 generally allows the central controller 14 to communicate with external systems, computing networks, telecommunication networks, the Internet, and the like. The communication element 38 may include signal and/or data transmitting and receiving circuits, such as antennas, amplifiers, filters, mixers, oscillators, digital signal processors (DSPs), and the like. The communication element 38 may establish communication wirelessly by utilizing RF signals and/or data that comply with communication standards such as cellular 2G, 3G, 4G, VoIP, LTE, VoLTE, or 5G, IEEE 802.11 standard such as WiFi, IEEE 802.16 standard such as WiMAX, Bluetooth™, or combinations thereof. In addition, the communication element 38 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 38 may establish communication through connectors or couplers that receive metal conductor wires or cables which are compatible with networking technologies such as ethernet. In certain embodiments, the communication element 38 may also couple with optical fiber cables. The communication element 38 may be in electronic communication with the memory element 40 and the processor 42.

The memory element 40 may be embodied by devices or components that store data in general, and digital or binary data in particular, and may include exemplary electronic hardware data storage devices or components such as read-only memory (ROM), programmable ROM, erasable programmable ROM, random-access memory (RAM) such as static RAM (SRAM) or dynamic RAM (DRAM), cache memory, hard disks, optical disks, flash memory, thumb drives, universal serial bus (USB) drives, solid state memory, or the like, or combinations thereof. In some embodiments, the memory element 40 may be embedded in, or packaged in the same package as, the processor 42. The memory element 40 may include, constitute, or embody, a non-transitory “computer-readable medium”. The memory element 40 may store the instructions, code, code statements, code segments, software, firmware, programs, applications, apps, services, daemons, or the like that are executed by the processor 42. The memory element 40 is in electronic communication with the processor 42 and may also store data that is received by the processor 42 or the device in which the processor 42 is implemented. The processor 42 may further store data or intermediate results generated during processing, calculations, and/or computations as well as data or final results after processing, calculations, and/or computations. In addition, the memory element 40 may store settings, lookup tables, databases, and the like. In some embodiments, the values of the current transmitter signal and the switch devices 32 with which they are associated, or correspond, may be listed in a lookup table or database stored in the memory element 40. As an example, each row of a first column of a lookup table or database may include a value of the current transmitter signal, and each row of a second column may include the identification of the switch device 32 to which the sensor unit 34 outputting the current transmitter signal is connected. In various embodiments, each row of a third column may include a location, a tower number, or a function of the switch device 32.

The processor 42 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The processor 42 may generally execute, process, or run instructions, code, code segments, code statements, software, firmware, programs, applications, apps, processes, services, daemons, or the like. The processor 42 may also include hardware components such as registers, finite-state machines, sequential and combinational logic, configurable logic blocks, and other electronic circuits that can perform the functions necessary for the operation of the current invention. In certain embodiments, the processor 42 may include multiple computational components and functional blocks that are packaged separately but function as a single unit. In some embodiments, the processor 42 may further include multiprocessor architectures, parallel processor architectures, processor clusters, and the like, which provide high performance computing. The processor 42 may be in electronic communication with the other electronic components of the central controller 14 through serial or parallel links that include universal busses, address busses, data busses, control lines, and the like. In addition, the processor 42 may include analog to digital converters (ADCs) to convert analog electronic signals to digital data values in binary form (such as by sampling), or streams of digital data values, and/or digital to analog converters (DACs) to convert digital data values, or streams of digital data values, to analog electronic signals.

The processor 42 is operable, configured, and/or programmed to perform the following functions, operations, processes, methods, and/or algorithms of the central controller 14 by utilizing hardware, software, firmware, or combinations thereof. Other components, such as the communication element 38 and the memory element 40 may be utilized as well. In certain embodiments, the central controller 14 may also have access to, and be in electronic communication with, cloud computing services, wherein a portion of the functions, operations, processes, methods, and/or algorithms of the central controller 14 are performed by computing resources off-site. Additionally, or alternatively, the processor 42 may include components, such as cloud computing components, that are physically located in a plurality of different geolocations but are able to function as a single unit.

The processor 42 receives a status signal from the safety circuit monitor 36. If the status signal has a value that indicates that the safety signal is being received, then the processor 42 takes no specific action. If the status signal has a value that indicates one of the switch devices 32 is open, then the processor 42 may delay for a short period of time in case one of the switch devices 32 momentarily opened and then closed again. After the delay, the processor 42 halts the operation of the irrigation system 10 by terminating the flow of water and stopping the movement of the towers 12. The safety circuit monitor 36 outputs the sensor identification signal which turns on the current transmitter 54 of the sensor unit 34 connected to the switch device 32 that opened. The current transmitter 54 outputs the current transmitter signal to the safety circuit monitor 36, which in turn, outputs the status signal having a value that indicates the identification of (at least) one open switch device 32 or the number or position of one of the towers 12 with an open switch device 32. In some embodiments, the processor 42 may retrieve all, or a portion, of a lookup table or database from the memory element 40. From the value of the status signal, the processor 42 determines, from the lookup table or database or by performing one or more calculations, algorithmic steps or the like, the identification or function of the open switch device 32 or the number or position of the tower 12 with the open switch device 32. The processor 42 may also transmit a (SMS) text or an email, or display a message on a local monitor indicating the identification or function of the open switch device 32 or the number or position of the tower 12 with the open switch device 32.

The irrigation system 10 may operate as follows with reference to FIGS. 1-4. The irrigation system 10 may be operating under normal parameters. That is, the drive motors 26 may be moving each tower 12 independently, perhaps at different speeds and at different times, such that the successive sections of the conduit 20 are rotating with respect to one another and the alignment angles between adjacent sections are within the safety threshold values. The safety circuit monitor 36 outputs and receives back the safety signal – indicating normal operation. The safety circuit monitor 36 outputs the status signal which has a value that indicates all the switch devices 32 are closed. When all of the switch devices 32 are closed, the first and second terminals 48, 50 of each sensor unit 34 are electrically shorted and have roughly zero Volts across them. As a result, none of the sensor units 34 output the current transmitter signal.

For one of any number of reasons, such as the tires getting stuck in a rut, a high wind event, or the like, one of the towers 12 may experience a problem that results in the alignment angle between the two sections of conduit 20 joined at the tower 12 exceeding the safety threshold value and one of the switch devices 32 opens. In addition, or instead, an over watering situation may occur, or an end of run barricade may be encountered, such that one of the switch devices 32 opens.

As a result, the first and second terminals 48, 50 of the sensor unit 34 electrically connected to the open switch device 32 experience an increased voltage (as an example, up to 120 V AC). The increased voltage is greater than the disconnect voltage level threshold causing the voltage sensing switch 52 to be in, or switch to, the high-impedance state. The combination of the switch device 32 opening and the sensor unit 34 being in the high-impedance state causes a loss of the safety signal, which is detected by the safety circuit monitor 36. The safety circuit monitor 36 stops outputting the safety signal and then outputs the status signal to the processor 42 having a second one of the values which indicates that one of the switch devices 32 is open. The processor 42 receives the status signal and may delay for a short period of time. After the delay, the processor 42 halts the operation of the irrigation system 10 by terminating the flow of water and stopping the movement of the towers 12.

After the irrigation system 10 is halted, the safety circuit monitor 36 outputs the sensor identification signal which turns on the current transmitter 54 of the sensor unit 34 connected to the switch device 32 that opened. The current transmitter 54 outputs the current transmitter signal to the safety circuit monitor 36, which in turn, outputs the current transmitter signal having a value which was programmed or set by a technician. The value varies according to an identification of the switch device 32, a function of the switch device 32, a location of the switch device 32, a location or position of the tower 12 in which the switch device 32 is implemented, or the like. The safety circuit monitor 36 receives the current transmitter signal and outputs the status signal to the processor 42, wherein the status signal has a value which indicates the identification or function of the open switch device 32 or a number or position of the tower 12 with the open switch device 32.

The processor 42 receives the status signal and may delay for a short period of time. After the delay, the processor 42 halts the operation of the irrigation system 10 by terminating the flow of water and stopping the movement of the towers 12. From the value of the status signal, the processor 42 determines the identification or function of the open switch device 32 or the number or position of the tower 12 with the open switch device 32. The processor 42 may also transmit a (SMS) text or an email, or display a message on a local monitor indicating the identification or function of the open switch device 32 or the number or position of the tower 12 with the open switch device 32. The text or email may be received by a technician on a mobile electronic device. Additionally, or alternatively, the technician may check the local monitor for the message.

In the event of a current surge, such as from a lightning strike, through the safety circuit 30, the fuse 58 of one or more sensor units 34 may blow, rendering the one or more sensor units 34 to be open circuits across the first and second terminals 48, 50. Assuming that the rest of the irrigation system 10 is still operational, the towers 12 are still being driven. If any of the switch devices 32 that is connected to a damaged sensor unit 34 opens, then the safety circuit 30 experiences an open circuit as a result of both the switch device 32 and the sensor unit 34 being open. Accordingly, the safety circuit monitor 36 detects that the safety signal is no longer being received and outputs the status signal having a value which indicates the safety circuit 30 is open. The processor 42 receives the status signal and may delay for a short period of time before halting the operation of the irrigation system 10. The safety circuit monitor 36 outputs the sensor identification signal. If the safety circuit monitor 36 does not receive a current transmitter signal within a certain time period, then the safety circuit monitor 36 outputs the status signal having a value which indicates an open fuse in one of the sensor units 34. The processor 42 receives the status signal and may transmit a (SMS) text or an email, or display a message on a local monitor indicating that one of the switch devices 32 is open and that one or more sensor units 34 may have an open fuse. The text or email may be received by a technician on a mobile electronic device. Additionally, or alternatively, the technician may check the local monitor for the message.

Having the fuse 58 in each sensor unit 34 provides fault tolerance and allows the irrigation system 10 to still operate safely in the situation where multiple safety events occur. For example, even if the fuse 58 in one or more sensor units 34 is open as a result of a first safety event, such as a current surge, the irrigation system 10 can still detect when a second safety event occurs, such as over watering or encountering the end of run, and safely halt operations.

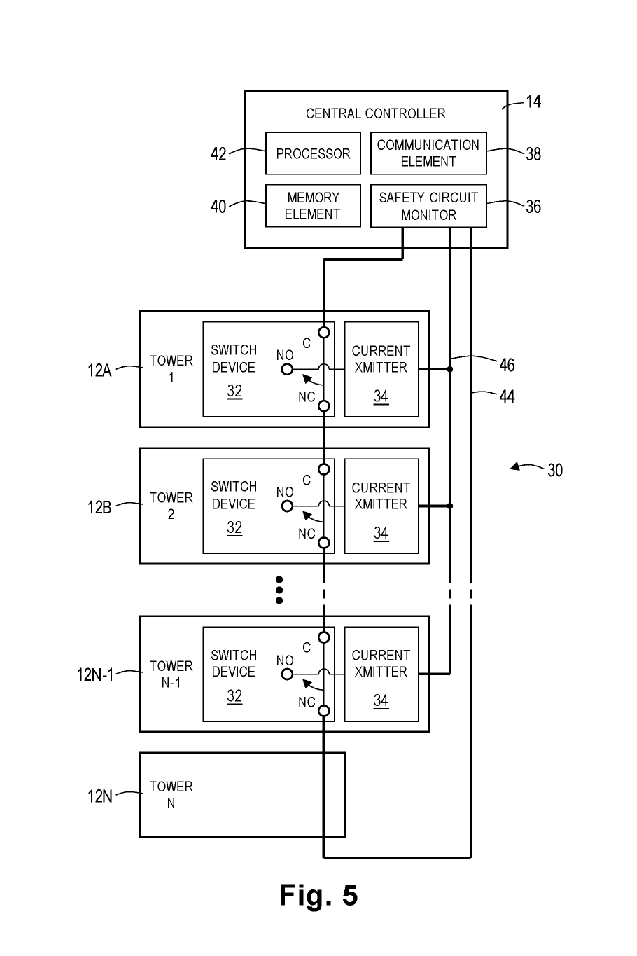

Referring to FIG. 5, a second configuration of the central controller 14 and the safety circuit 30 is shown, highlighting the electrical connection between each switch device 32 and its associated sensor unit 34. The safety circuit 30 may also include switch devices 32 for other functions, such as over water monitoring, although they are not shown in FIG. 5. The components of the central controller 14, the switch devices 32, and the sensor units 34 all operate in the same manner as described above for the first configuration. The difference lies in the electrical connectivity of the sensor units 34 and the usage of a second cable 46. For switch devices 32 that have the configuration shown in FIGS. 4 and 5, the first terminal 48 of each sensor unit 34 is electrically connected to the normally open terminal NO of the associated switch device 32, and the second terminal 50 of each sensor unit 34 is electrically connected to the second cable 46 – although the first terminal 48 may be electrically connected to the second cable 46 and the second terminal 50 may be electrically connected to the normally open terminal NO. The second cable 46 may be a neutral wire or other wire or cable that is also electrically connected to the safety circuit monitor 36.

The irrigation system 10 with reference to FIGS. 1 and 5 may operate as follows. The irrigation system 10 may be operating under normal parameters. That is, the drive motors 26 may be moving each tower 12 independently, perhaps at different speeds and at different times, such that the successive sections of the conduit 20 are rotating with respect to one another and the alignment angles between adjacent sections are within the safety threshold values. The safety circuit monitor 36 outputs and receives back the safety signal – indicating normal operation. The safety circuit monitor 36 outputs the status signal which has a value that indicates all the switch devices 32 are closed. When all of the switch devices 32 are closed, the first and second terminals 48, 50 of each sensor unit 34 are electrically shorted and have roughly zero Volts across them. As a result, none of the sensor units 34 output the current transmitter signal. If any of the switch devices 32, with the electrical connection to the sensor unit 34 as shown in FIG. 5, opens, then the associated sensor unit 34 receives voltage greater than the disconnect voltage level threshold through the normally open contact NO and the second cable 46. If any of the other switch devices 32 opens, then the sensor unit 34 operates as discussed above for the embodiments shown in FIGS. 2-4. Using either embodiment, the safety circuit monitor 36 detects an open circuit and then the irrigation system 10 operates in the same manner as discussed above by shutting down and determining which safety device 32 opened.

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processor, may be implemented as special purpose or as general purpose. For example, the processor may comprise dedicated circuitry or logic that is permanently configured, such as an application-specific integrated circuit (ASIC), or indefinitely configured, such as an FPGA, to perform certain operations. The processor may also comprise programmable logic or circuitry (e.g., as encompassed within a general-purpose processor or other programmable processor) that is temporarily configured by software to perform certain operations. It will be appreciated that the decision to implement the processor as special purpose, in dedicated and permanently configured circuitry, or as general purpose (e.g., configured by software) may be driven by cost and time considerations.

Accordingly, the term “processor” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processor is temporarily configured (e.g., programmed), each of the processors need not be configured or instantiated at any one instance in time. For example, where the processor comprises a general-purpose processor configured using software, the general-purpose processor may be configured as respective different processors at different times. Software may accordingly configure the processor to constitute a particular hardware configuration at one instance of time and to constitute a different hardware configuration at a different instance of time.

Computer hardware components, such as communication elements, memory elements, processors, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processors may be located in a single location (e.g., within a home environment, an office environment or as a server farm), while in other embodiments the processors may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processor and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

1. A sensor unit comprising:
a first terminal and a second terminal configured to electrically connect to a device;
a voltage sensing switch configured to sense an electric voltage between the first terminal and the second terminal, the voltage sensing switch configured to be in a high-impedance state if the voltage between the first terminal and the second terminal is greater than a disconnect voltage level threshold; and
a current transmitter configured to output a current transmitter signal if the voltage between the first terminal and the second terminal is greater than or equal to a first turn on voltage level threshold and less than or equal to a second turn on voltage level threshold.

2. The sensor unit of claim 1, further comprising a user interface configured to receive an input from a user and set a value of the current transmitter signal according to the input.

3. The sensor unit of claim 2, wherein the value of the current transmitter signal includes an electric current having a selective direct current level.

4. The sensor unit of claim 2, wherein the value of the current transmitter signal includes a sequence of binary data pulses.

5. The sensor unit of claim 1, further comprising a fuse sensitive to electric current flowing through the sensor unit and configured to open and prevent the flow of electric current through the sensor unit if the electric current flowing through the sensor unit exceeds a first current level threshold.

6. The sensor unit of claim 1, wherein the voltage sensing switch is in a low-impedance state when the voltage between the first terminal and the second terminal is less than or equal to the disconnect voltage level threshold.

7. An irrigation system comprising:
a plurality of switch devices, each switch device including a first contact and a second contact and being either closed or open, each switch device being electrically connected to at least one other switch device;
a plurality of sensor units, each sensor unit including
a first terminal and a second terminal, the first terminal being electrically connected to the first contact of a respective one of the switch devices, and the second terminal being electrically connected to the second contact of the respective one of the switch devices,
a voltage sensing switch configured to sense an electric voltage between the first terminal and the second terminal, the voltage sensing switch configured to be in a high-impedance state if the voltage between the first terminal and the second terminal is greater than a disconnect voltage level threshold,
a current transmitter configured to output a current transmitter signal if the voltage between the first terminal and the second terminal is greater than or equal to a first turn on voltage level threshold and less than or equal to a second turn on voltage level threshold; and
a central controller configured to:
output a safety signal having a voltage greater than the disconnect voltage level threshold such that the voltage sensing switch of one of the sensor units is in the high-impedance state if the switch device to which it is electrically connected opens.

8. The irrigation system of claim 7, wherein the central controller is further configured to:
cease outputting the safety signal if one of the switch devices opens, and
output a sensor identification signal having a voltage greater than or equal to the first turn on voltage level threshold and less than or equal to the second turn on voltage level threshold such that the current transmitter of one of the sensor units outputs the current transmitter signal if the switch device to which it is electrically connected opens.

9. The irrigation system of claim 7, wherein each sensor unit further includes a user interface configured to receive an input from a user and set a value of the current transmitter signal according to the input.

10. The irrigation system of claim 9, wherein the value of the current transmitter signal from each sensor unit varies according to an identification or function of the open switch device to which the sensor unit is electrically connected or a number or position of a tower with which the open switch device, to which the sensor unit is electrically connected, is associated.

11. The irrigation system of claim 9, wherein the value of the current transmitter signal from each sensor unit includes an electric current having a selective direct current level.

12. The irrigation system of claim 9, wherein the value of the current transmitter signal from each sensor unit includes a sequence of binary data pulses.

13. The irrigation system of claim 7, wherein each sensor unit is in a low-impedance state when its current transmitter is outputting the current transmitter signal.

14. An irrigation system comprising:
a plurality of switch devices, each switch device including a first contact and a second contact and being either closed or open, each switch device being electrically connected to at least one other switch device;
a plurality of sensor units, each sensor unit including
a first terminal and a second terminal, the first terminal being electrically connected to the first contact of a respective one of the switch devices, and the second terminal being electrically connected to the second contact of the respective one of the switch devices,
a voltage sensing switch configured to sense an electric voltage between the first terminal and the second terminal, the voltage sensing switch configured to be in a high-impedance state if the voltage between the first terminal and the second terminal is greater than a disconnect voltage level threshold,
a current transmitter configured to output a current transmitter signal if the voltage between the first terminal and the second terminal is greater than or equal to a first turn on voltage level threshold and less than or equal to a second turn on voltage level threshold; and
a central controller configured to:
output a sensor identification signal having a voltage greater than or equal to the first turn on voltage level threshold and less than or equal to the second turn on voltage level threshold such that the current transmitter of one of the sensor units outputs the current transmitter signal if the switch device to which it is electrically connected opens.

15. The irrigation system of claim 14, wherein the central controller is further configured to:
output a safety signal having a voltage greater than the disconnect voltage level threshold such that the voltage sensing switch of one of the sensor units is in the high-impedance state if the switch device to which it is electrically connected opens,
cease outputting the safety signal if one of the switch devices opens, and
output the sensor identification signal.

16. The irrigation system of claim 14, wherein each sensor unit further includes a user interface configured to receive an input from a user and set a value of the current transmitter signal according to the input.

17. The irrigation system of claim 16, wherein the value of the current transmitter signal from each sensor unit varies according to an identification or function of the open switch device to which the sensor unit is electrically connected or a number or position of a tower with which the open switch device, to which the sensor unit is electrically connected, is associated.

18. The irrigation system of claim 16, wherein the value of the current transmitter signal from each sensor unit includes an electric current having a selective direct current level.

19. The irrigation system of claim 16, wherein the value of the current transmitter signal from each sensor unit includes a sequence of binary data pulses.

20. The irrigation system of claim 14, wherein each sensor unit is in a low-impedance state when its current transmitter is outputting the current transmitter signal.
